(19) United States
(12) Patent Application Publication
(10) Pub. No.: US 2014/0363573 A1
(43) Pub. Date: Dec. 11, 2014

(54) EVAPORATION DEVICE AND EVAPORATION METHOD THEREOF

(71) Applicant: EverDisplay Optronics (Shanghai) Limited, Shanghai (CN)

(72) Inventors: Chiachen LI, Shanghai (CN); Tianwang HUANG, Shanghai (CN)

(73) Assignee: EverDisplay Optronics (Shanghai) Limited, Shanghai (CN)

(21) Appl. No.: 14/298,439

(22) Filed: Jun. 6, 2014

(30) Foreign Application Priority Data
Jun. 6, 2013 (CN) 201310225232.2

(51) Int. Cl. C23C 16/04

(52) U.S. Cl. CPC C23C 16/042
USPC 427/248.1; 118/720

(57) ABSTRACT

The disclosure discloses an evaporation device and evaporation method. The evaporation device includes a main chamber for accommodating the evaporation source and the substrate; a first extension chamber and a second extension chamber respectively and alternately communicating with the main chamber; and a first metal mask inside the first extension chamber, intermittently entering the main chamber, and a second metal mask inside the second extension chamber, intermittently entering the main chamber with respective to the first metal mask, such that the evaporation material is able to pass the first or the second metal mask and then on the substrate.

### CROSS-REFERENCE TO RELATED APPLICATIONS

This application claims the benefits of Chinese Patent Application No. 201310225232.2, filed on Jun. 6, 2013 in the Patent Office of China, the disclosure of which is incorporated herein by reference in its entirety.

### TECHNICAL FIELD

The present disclosure relates to an evaporation device and an evaporation method thereof.

### BACKGROUND

Evaporation is a process that heats and evaporates evaporation material in an evaporation source under vacuum, so that large amounts of atoms and molecules are vaporized to escape from evaporation source and adhere to a substrate to form a film layer. FIG. 1 illustrates a schematic diagram of existing conventional evaporation device with a fixed evaporation source. As shown in FIG. 1, the evaporation device includes a main chamber 1′, a fixed evaporation source 2′ disposed in the main chamber 1′, a substrate 3′ and a metal mask 4′. The fixed evaporation source 2′ is disposed at the bottom of the main chamber 1′, the substrate 3′ is disposed above the fixed evaporation source 2′ and right faces the fixed evaporation source 3′, and the metal mask 4′ is disposed between the fixed evaporation source 2′ and the substrate 3′, as the mask for the substrate 3′ during evaporation. The metal mask 4′ is used for shielding a part of a glass surface of the substrate 3′ that does not need to deposit organic materials or metal materials. The fixed evaporation source 2′ contains evaporation material, which is heated to evaporation temperature and vaporized, and then goes through the metal mask 4′ and is deposited on the substrate 3′ during evaporation. The substrate 3′ can rotate around rotation shaft 31′, to obtain an even film layer after evaporation.

The largest drawback of conventional evaporation device is the low utilization rate of material. Specifically, most of material adheres to walls of the main chamber 1′ and the metal mask 4′, and only about 1.5% of material is deposited to the substrate 3′. To reduce waste of material, after each evaporation operation, the metal mask 4′ needs to be taken out by breaking the vacuum of the evaporation device, to recycle the evaporation material adhered to it by manual scraping. However, frequent breaks of vacuum may introduce impurities into the evaporation device, and manual scraping not only costs time and human labor, but also affects the utilization rate of the device.

The above information disclosed in this Background section is only for enhancement of understanding of the background of the disclosure and therefore it may contain information that does not form the prior art that is already known in this country to a person of ordinary skill in the art.

### SUMMARY

An object of the present disclosure is to provide an evaporation device and an evaporation method thereof, to solve above-mentioned and other problems.

To solve the problems above, the present disclosure provides an evaporation device, for depositing evaporation material accommodated in an evaporation source to a substrate, the evaporation device comprising:

a main chamber for accommodating the evaporation source and the substrate;

a first extension chamber and a second extension chamber respectively and alternately communicating with the main chamber; and

a first metal mask inside the first extension chamber, intermittently entering the main chamber, and a second metal mask inside the second extension chamber, intermittently entering the main chamber with respective to the first metal mask, such that the evaporation material is able to pass the first or the second metal mask and then on the substrate.

Preferably, the first extension chamber and the second extension chamber are respectively positioned at two sides of the main chamber.

Preferably, the main chamber has a first opening and a second opening at its two sides corresponding to the first extension chamber and the second extension chamber; the first extension chamber has a first extension chamber opening corresponding to the first opening, and the second extension chamber has a second extension chamber opening corresponding to the second opening, such that the first metal mask is able to enter the main chamber through the first extension chamber opening and the first opening, and the second metal mask is able to enter the main chamber through the second extension chamber opening and the second opening.

Preferably, the main chamber further comprises a first valve corresponding to the first opening for isolating the main chamber from the first extension chamber, and a second valve corresponding to the second opening for isolating the main chamber from the second extension chamber.

Preferably, the first extension chamber comprises a first rotation shaft, and the second extension chamber comprises a second rotation shaft; the first metal mask is connected to the first rotation shaft, and the second metal mask is connected to the second rotation shaft; such that in case that the first valve or the second valve is opened, the first rotation shaft or the second rotation shaft rotates whereby the first metal mask and the second metal mask alternately enter the main chamber.

Preferably, the first extension chamber and the second extension chamber are respectively connected to two sides of the main chamber detachably.

Preferably, the evaporation device further comprises a first cleaning component inside the first extension chamber to clean the evaporation material on the first metal mask, and a second cleaning component inside the second extension chamber to clean the evaporation material on the second metal mask.

Preferably, the first cleaning component is in a form of a scraping arm and comprises a first scraping head; the second cleaning component is in the form of a scraping arm and comprises a second scraping head; such that the first scraping head and the second scraping head are able to scrap the evaporation material on the first metal mask and the second metal mask in reciprocating motion.

Preferably, the first cleaning component and the second cleaning component respectively extend from a sidewall of the first extension clamber and a sidewall of the second extension clamber, and respectively position below the first metal mask and the second metal mask.

Preferably, evaporation device further comprises a first tray inside the first extension chamber to contain the evaporation material scraped from the first metal mask, and a second tray inside the second extension chamber to contain the evaporation material scraped from the second metal mask.

Preferably, each of the main chamber, the first extension chamber and the second extension chamber comprises a door to open or close the main chamber, the first extension chamber and the second extension chamber, respectively.

Another aspect of the disclosure discloses an evaporation method, for depositing evaporation material accommodated in an evaporation source on a substrate in an evaporation device, the evaporation device including a main chamber, a first extension chamber and a second extension chamber respectively and alternatively communicating with the main chamber, the evaporation method comprising the steps of:

moving a first metal mask into the main chamber from the first extension chamber;

processing a first evaporation operation to cause the evaporation material being able to pass the first metal mask and on the substrate;

returning the first metal mask back to the first extension chamber from the main chamber, and isolating the main chamber and the first extension chamber from each other;

moving a second metal mask into the main chamber from the second extension chamber;

processing a second evaporation operation to cause the evaporation material being able to pass the second metal mask and on the substrate; and,

returning the second metal mask back to the second extension chamber from the main chamber, and isolating the main chamber and the second extension chamber from each other.

Preferably, the evaporation method further comprises a step of cleaning the evaporation material on the first metal mask in the first extension chamber during the second evaporation operation.

Preferably, all the steps are repeatedly performed.

Compared with the conventional technology, working efficiency according to the disclosure is improved, for two metal masks can be alternately used during evaporation. In addition, in some embodiments, the first extension chamber and the second extension chamber respectively have the first cleaning component and the second cleaning component, so the evaporation material on the first metal mask and the second metal mask can be alternately cleaned, which can greatly improve the utilization rate of the device of evaporation device.

The foregoing summary is not intended to summarize each potential embodiment or every aspect of the present disclosure.

### BRIEF DESCRIPTION OF THE DRAWINGS

The foregoing and other features and advantages of the disclosure will be apparent to those skilled in the art in view of the following detailed description, taken in conjunction with the accompanying drawings.

FIG. 1 illustrates a schematic diagram of one existing evaporation device with fixed evaporation source.

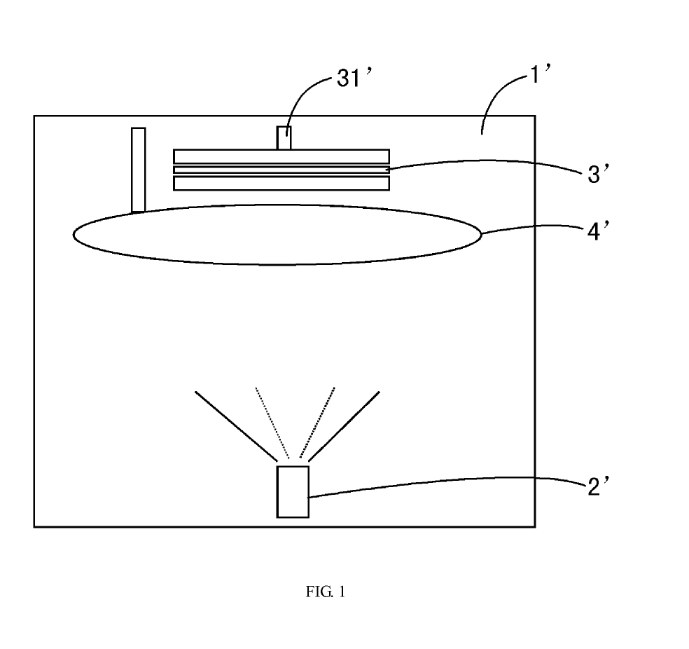

FIG. 2 illustrates a schematic diagram of the evaporation device according to an embodiment of the disclosure.

### DETAILED DESCRIPTION

Exemplary embodiments of the disclosure will now be described more fully with reference to the accompanying drawings, in which exemplary embodiments are shown. Exemplary embodiments of the disclosure may, however, be embodied in many different forms and should not be construed as being limited to the embodiments set forth herein; rather, these embodiments are provided so that this disclosure will be thorough and complete, and will fully convey the concept of exemplary embodiments to those skilled in the art. In the drawings, the thicknesses of layers and regions are exaggerated for clarity. Like reference numerals in the drawings denote like elements, and thus their description will be omitted.

The described features, structures, or/and characteristics of the disclosure may be combined in any suitable manner in one or more embodiments. In the following description, numerous specific details are disclosed to provide a thorough understanding of embodiments of the disclosure. One skilled in the relevant art will recognize, however, that the disclosure may be practiced without one or more of the specific details, or with other methods, components, materials, and so forth. In other instances, well-known structures, materials, or operations are not shown or described in detail to avoid obscuring aspects of the disclosure.

An evaporation device is provided for depositing evaporation material accommodated in an evaporation source to a substrate, the evaporation device comprising:

a main chamber for accommodating the evaporation source and the substrate;

a first extension chamber and a second extension chamber respectively and alternately communicating with the main chamber; and

a first metal mask inside the first extension chamber, intermittently entering the main chamber, and a second metal mask inside the second extension chamber, intermittently entering the main chamber with respective to the first metal mask, such that the evaporation material is able to pass the first or the second metal mask and then on the substrate.

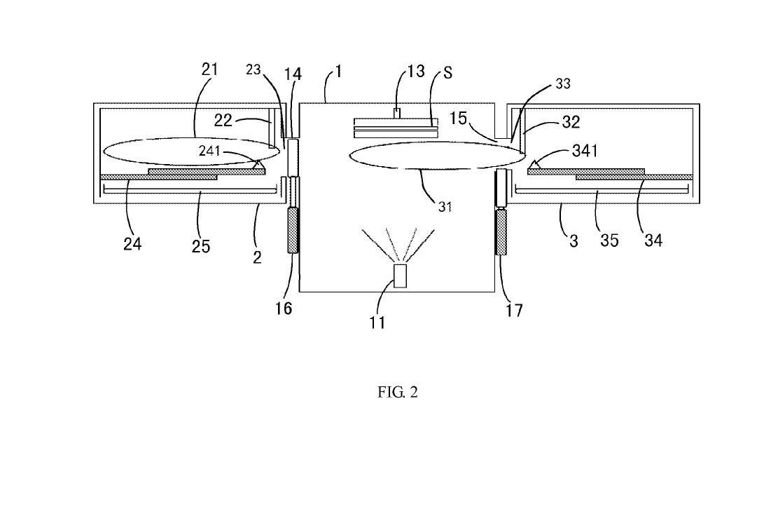

FIG. 2 illustrates a schematic diagram of an evaporation device according to an embodiment of the disclosure.

As shown in FIG. 2, the evaporation device in an embodiment of the disclosure comprises a main chamber 1, a first extension chamber 2 and a second extension chamber 3.

A fixed evaporation source 11 and a substrate S are disposed in the main chamber 1. The fixed evaporation source 11 may be disposed at the bottom of the main chamber 1, and the substrate S may be disposed above the fixed evaporation source 11 and right faces the fixed evaporation source 11. The fixed evaporation source 11 can contain evaporation material, and the evaporation material is heated to evaporation temperature and vaporized, and then deposited on the substrate S. The substrate S can rotate around a rotation shaft 13 disposed inside the main chamber and located at the top of the main chamber 1 in an evaporation operation, to get an even film layer after evaporation.

In the embodiment, the first extension chamber 2 and the second extension chamber 3 are respectively disposed at two sides of the main chamber 1. The main chamber 1 has a first opening 14 and a second opening 15 respectively disposed at the two sides corresponding to the first extension chamber 2 and the second extension chamber 3. The first extension chamber 2 has a first extension chamber opening 23 at the position corresponding to the first opening 14, and the second extension chamber 3 has a second extension chamber opening 33 at the position corresponding to the second opening 15.

In this embodiment, the main chamber 1 further comprises a first valve 16 corresponding to the first opening 14 and a second valve 17 corresponding to the second opening 15. When the first valve 16 is opened, the main chamber 1 and the first extension chamber 2 communicate with each other; when the second valve 17 is opened, the main chamber 1 and the second extension chamber 3 communicate with each other. On the contrary, when the first valve 16 is closed, the main chamber 1 and the first extension chamber 2 are isolated from each other; when the second valve 17 is closed, the main chamber 1 and the second extension chamber 3 are isolated from each other.

In other embodiments, it is also possible to dispose valves at the first extension chamber opening 23 and the second extension chamber opening 33 instead of the first valve 16 and the second valve 17 at the main chamber 1. However, methods for the communication and isolation between the main chamber 1 and the first extension chamber 2 or the second extension chamber 3 are not limited thereto. All structures which can realize the communication and isolation between the chambers are available. Moreover, it is also possible to dispose corresponding valves on the first extension chamber opening 23 and the second extension chamber opening 33 besides disposing the first valve 16 and the second valve 17, for better isolation effect.

The first extension chamber 2 has a first metal mask 21 and a first rotation shaft 22 inside. The second extension chamber 3 has a second metal mask 31 and a second rotation shaft 32 inside. The first rotation shaft 22 is disposed at the position near the first extension chamber opening 23, and the second rotation shaft 32 is disposed at the position near the second extension chamber opening 33. In the embodiment, the first rotation shaft 22 is connected to an end of the first metal mask 21 from the upper side of the first metal mask 21, and the second rotation shaft 32 is connected to an end of the second metal mask 31 from the upper side of the second metal mask 31. The first metal mask 21 can rotate around the first rotation shaft 22, to enter the main chamber 1 through the first extension chamber opening 23 and the first opening 14 or return to the first extension chamber 2 from the main chamber 1. The second metal mask 31 can rotate around the second rotation shaft 32, to enter the main chamber 1 through the second extension chamber opening 33 and the second opening 15 or return to the second extension chamber 3 from the main chamber 1. In case that the first valve 16 or the second valve 17 is opened, the first rotation shaft 22 or the second rotation shaft 32 rotates whereby the first metal mask 21 and the second metal mask 31 alternately enter the main chamber. The first metal mask 21 and the second metal mask 31 can be alternately used as a mask for the substrate S.

The first extension chamber 2 further includes a first cleaning component 24 inside it. The first cleaning component 24 is, for example, in a form of a scraping arm. The second extension chamber 3 further includes a second cleaning component 34 inside it. The second cleaning component 34 is, for example, in a form of a scraping arm too. The first cleaning component 24 and the second cleaning component 34 are respectively disposed under the first metal mask 21 and the second metal mask 31, to clean the evaporation material at the bottom of the first metal mask 21 and the second metal mask 31 from the lower part of the first metal mask 21 and the second metal mask 31.

In the embodiment, the first cleaning component 24 extends from a sidewall of the first extension chamber 2 which is far away from the first extension chamber opening 23. It can scrape the evaporation material on the first metal mask 21 with reciprocating motion of the first scraping head 241. The second cleaning component 34 extends from the sidewall of the second extension chamber 3 which is far away from the second extension chamber opening 33. It can scrape the evaporation material on the second metal mask 31 with reciprocating motion of the second scraping head 341. In other embodiments, disposing manners and locations of the first cleaning component 24 and the second cleaning component 34 may be varied, and the disclosure does not limit the disposing manners and locations as long as the evaporation material on the first metal mask 21 and the second metal mask 31 can be cleaned. The person skilled in the art can make any change based on the disclosure.

In the embodiment, in order to facilitate the user to recycle the evaporation material, the first extension chamber 2 further includes a first tray 25 for containing the evaporation material scraped from the first metal mask 21, and the second extension chamber 3 further includes a second tray 35 for containing the evaporation material scraped from the second metal mask 31.

The working process of the evaporation device according to the disclosure is illustrated hereinbelow.

When depositing evaporation material on the substrate S, the first valve 16 or the second valve 17 of the main chamber 1 is opened. Taking opening the first valve 16 as an example, the first metal mask 21 rotates around the first rotation shaft 22, enters the main chamber 1 through the first extension chamber opening 23 and the first opening 14, and is used as a mask for the substrate S during evaporation operation.

After evaporation, the first metal mask rotates around the first rotation shaft 22 reversely and returns to the first extension chamber 2. Then the first valve 16 is closed to isolate the main chamber 1 and the first extension chamber 2 from each other.

In next evaporation operation, the second valve 17 is opened, and the second metal mask 31 rotates around the second rotation shaft 32, enters the main chamber 1 through the second extension chamber opening 33 and the second opening 15, and is used as a mask for the substrate S. Meanwhile, in the first extension chamber 2, the first cleaning component 24 cleans the evaporation material on the first metal mask 21 with reciprocating motion of the first scraping head 241, for being used in the next evaporation operation. Thus, the first metal mask 21 and the second metal mask 31 can be used alternately.

Based on above description, the disclosure also discloses an evaporation method for depositing evaporation material accommodated in an evaporation source on a substrate in an evaporation device, the evaporation device including a main chamber, a first extension chamber and a second extension chamber respectively and alternatively communicating with the main chamber, the evaporation method comprising the steps of:

moving a first metal mask into the main chamber from the first extension chamber;

processing a first evaporation operation to cause the evaporation material being able to pass the first metal mask and on the substrate;

returning the first metal mask back to the first extension chamber from the main chamber, and isolating the main chamber and the first extension chamber from each other;

moving a second metal mask into the main chamber from the second extension chamber;

processing a second evaporation operation to cause the evaporation material being able to pass the second metal mask and on the substrate; and,

returning the second metal mask back to the second extension chamber from the main chamber, and isolating the main chamber and the second extension chamber from each other.

The present embodiment provides an evaporation method for depositing the evaporation material accommodated in the fixed evaporation source 11 to the substrate S in the evaporation device. The evaporation device comprises the main chamber 1, the first extension chamber 2 and the second extension chamber 3, each of which can communicate with the main chamber 1 or be isolated from the main chamber 1. The evaporation method comprises:

Step 1: moving the first metal mask 21 into the main chamber 1 from the first extension chamber 2, to use the first metal mask as a mask for the substrate S in a first evaporation operation;

Step 2: after the first evaporation operation, returning the first metal mask 21 to the first extension chamber 2 from the main chamber 1, and isolating the main chamber 1 and the first extension chamber 2 from each other;

Step 3: moving the second metal mask 31 into the main chamber 1 from the second extension chamber 3, to use the second metal mask as a mask for the substrate S in a second evaporation operation; and

Step 4: after the second evaporation operation, returning the second metal mask 31 to the second extension chamber 3 from the main chamber 1, and isolating the main chamber 1 and the second extension chamber 3 from each other.

In one embodiment of the evaporation method according to the disclosure, the evaporation material on the first metal mask 21 is cleaned in the first extension chamber 2 during the second evaporation operation.

The first metal mask 21 and the second metal mask 31 can be used in turn during evaporation, so the operating efficiency can be improved. Meanwhile, the first extension chamber 2 and the second extension chamber 3 respectively have the first cleaning component 24 and the second cleaning component 34, therefore the first metal mask 21 and the second metal mask 31 can alternately clean the evaporation material, instead of performing the steps of the conventional technology such as breaking the vacuum first, taking out the metal mask, cleaning, and assembling the metal mask back. So the utilization rate of the device is greatly improved.

The first extension chamber 2 and the second extension chamber 3 according to the disclosure are respectively connected to two sides of the main chamber 1 detachably, to facilitate the maintenance. In addition, a door can be respectively disposed at the front side of each of the main chamber 1, the first extension chamber 2 and the second extension chamber 3 (the front side is the side shown in FIG. 2), to facilitate to open or close the chambers, especially to open the first extension chamber 2 and the second extension chamber 3 for taking out the first metal mask 21 and the second metal mask 31 for further cleaning, or taking out the first tray 25 and the second tray 35 to recycle the evaporation material.

The disclosure can be applied to, for example, evaporation of organic material of Organic Light Emitting Diode with a fixed evaporation source. The substrate S is, for example, a glass substrate. The substrate S has a mask on it. Compared to the conventional technology, the disclosure may have one or more of the following technical effects.

1. Two metal masks can be alternately used during evaporation, which improves the working efficiency.

2. The cleaning components in the two extension chambers can clean the evaporation material automatically, and evaporation material can be recycled, which reduces manual operation and recycling time of evaporation.

3. The two metal masks can be alternately used and cleaned, therefore a continuous evaporation operation can be achieved, which can improve the working efficiency and the utilization rate of the evaporation device.

Exemplary embodiments have been specifically shown and described as above. It will be appreciated by those skilled in the art that the disclosure is not limited the disclosed embodiments; rather, all suitable modifications and equivalent which come within the spirit and scope of the appended claims are intended to fall within the scope of the disclosure.

What is claimed is:

1. An evaporation device, for depositing evaporation material accommodated in an evaporation source to a substrate, the evaporation device comprising:
a main chamber for accommodating the evaporation source and the substrate;
a first extension chamber and a second extension chamber respectively and alternately communicating with the main chamber; and
a first metal mask inside the first extension chamber, intermittently entering the main chamber, and a second metal mask inside the second extension chamber, intermittently entering the main chamber with respective to the first metal mask, such that the evaporation material is able to pass the first or the second metal mask and then on the substrate.

2. The evaporation device according to claim 1, wherein, the first extension chamber and the second extension chamber are respectively positioned at two sides of the main chamber.

3. The evaporation device according to claim 1, wherein, the main chamber has a first opening and a second opening at its two sides corresponding to the first extension chamber and the second extension chamber; the first extension chamber has a first extension chamber opening corresponding to the first opening, and the second extension chamber has a second extension chamber opening corresponding to the second opening, such that the first metal mask is able to enter the main chamber through the first extension chamber opening and the first opening, and the second metal mask is able to enter the main chamber through the second extension chamber opening and the second opening.

4. The evaporation device according to claim 3, wherein, the main chamber further comprises a first valve corresponding to the first opening for isolating the main chamber from the first extension chamber, and a second valve corresponding to the second opening for isolating the main chamber from the second extension chamber.

5. The evaporation device according to claim 4, wherein, the first extension chamber comprises a first rotation shaft, and the second extension chamber comprises a second rotation shaft; the first metal mask is connected to the first rotation shaft, and the second metal mask is connected to the second rotation shaft; such that in case that the first valve or the second valve is opened, the first rotation shaft or the second rotation shaft rotates whereby the first metal mask and the second metal mask alternately enter the main chamber.

6. The evaporation device according to claim 1, wherein, the first extension chamber and the second extension chamber are respectively connected to two sides of the main chamber detachably.

7. The evaporation device according to claim 1, further comprising a first cleaning component inside the first extension chamber to clean the evaporation material on the first metal mask, and a second cleaning component inside the second extension chamber to clean the evaporation material on the second metal mask.

8. The evaporation device according to claim 7, wherein, the first cleaning component is in a form of a scraping arm and comprises a first scraping head; the second cleaning component is in the form of a scraping arm and comprises a second scraping head; such that the first scraping head and the second scraping head are able to scrap the evaporation material on the first metal mask and the second metal mask in reciprocating motion.

9. The evaporation device according to claim 7, wherein, the first cleaning component and the second cleaning component respectively extend from a sidewall of the first extension clamber and a sidewall of the second extension clamber, and respectively position below the first metal mask and the second metal mask.

10. The evaporation device according to claim 7, further comprising a first tray inside the first extension chamber to contain the evaporation material scraped from the first metal mask, and a second tray inside the second extension chamber to contain the evaporation material scraped from the second metal mask.

11. The evaporation device according to claim 1, wherein, each of the main chamber, the first extension chamber and the second extension chamber comprises a door to open or close the main chamber, the first extension chamber and the second extension chamber, respectively.

12. An evaporation method, for depositing evaporation material accommodated in an evaporation source on a substrate in an evaporation device, the evaporation device including a main chamber, a first extension chamber and a second extension chamber respectively and alternatively communicating with the main chamber, the evaporation method comprising the steps of:
moving a first metal mask into the main chamber from the first extension chamber;
processing a first evaporation operation to cause the evaporation material being able to pass the first metal mask and on the substrate;
returning the first metal mask back to the first extension chamber from the main chamber, and isolating the main chamber and the first extension chamber from each other;
moving a second metal mask into the main chamber from the second extension chamber;
processing a second evaporation operation to cause the evaporation material being able to pass the second metal mask and on the substrate; and,
returning the second metal mask back to the second extension chamber from the main chamber, and isolating the main chamber and the second extension chamber from each other.

13. The evaporation method according to claim 12, further comprising a step of cleaning the evaporation material on the first metal mask in the first extension chamber during the second evaporation operation.

14. The evaporation method according to claim 12, wherein, all the steps are repeatedly performed.
